(19) United States
(12) Patent Application Publication
(10) Pub. No.: US 2006/0220070 A1
(43) Pub. Date: Oct. 5, 2006

(54) Imaging system and driving method

(76) Inventors: Shinichiro Izawa, Motosu-shi (JP); Kazutaka Itsumi, Anpachi-gun (JP); Yuzo Otsuru, Anpachi-gun (JP); Yoshihiro Okada, Hashima-shi (JP)

Correspondence Address: CANTOR COLBURN, LLP, 55 GRIFFIN ROAD SOUTH, BLOOMFIELD, CT, 06002, US

(21) Appl. No.: 11/367,237

(22) Filed: Mar. 3, 2006

(30) Foreign Application Priority Data
Mar. 4, 2005 (JP) 2005-060968

(51) Int. Cl. H01L 29/768

(52) U.S. Cl. 257/239

(57) ABSTRACT

An imaging system, capable of reducing blooming in a solid-state imaging device and improving image sensitivity, comprises an imaging section which has at least three transfer electrodes and is continuously arranged with pixels for producing information charges in response to the light from the outside, wherein the information charges are stored and transferred using potential wells formed by potentials applied to the transfer electrodes and, during image capture, one of the transfer electrodes is maintained in an ON state and at least another one of the transfer electrodes is alternately switched between an ON state and an OFF state. It is more preferable to average the amount of generated dark current under the transfer electrodes by switching the transfer electrodes between an ON state and an OFF state for image capture. This provides restraint of a difference in the amount of generated dark current between pixels, thus reducing image graininess.

### PRIORITY INFORMATION

This application claims priority to Japanese Patent Application No. 2005-60968 filed on Mar. 4, 2005, which is incorporated herein by reference in its entirety.

### BACKGROUND OF THE INVENTION

1. Field of the Invention

The present invention relates to an imaging system and driving method for improving the quality of captured images.

2. Description of the Related Art

Charged Coupled Device (CCD) image sensors are charge-transfer devices that transfer information charges produced in pixels arranged in a matrix manner in synchronism with an external clock pulse, as a batch of signal packets.

As illustrated in FIG. 4, a frame transfer system CCD image sensor comprises an imaging section 2i, a storage section 2s, a horizontal transfer section 2h, and an output section 2d. The imaging section 2i is equipped with a plurality of vertical shift registers extending vertically (as shown in FIG. 4) and parallel to each other. Each bit of the respective vertical shift registers functions as a photo diode disposed to serve as a two-dimensional matrix. The storage section 2s is equipped with a plurality of vertical shift registers extending vertically and parallel to each other. The respective vertical shift registers of the storage section 2s are arranged so as to be continuous with one of the vertical shift registers provided in the imaging section 2i. The storage section 2s is light-shielded and causes the respective bits of the respective vertical shift registers to function as storage pixels which store information charges transferred from the imaging section 2i. The horizontal transfer section 2h is equipped with horizontal shift registers arranged extending horizontally (lateral direction in FIG. 4). The respective bits of the horizontal shift registers are connected with outputs of the respective vertical shift registers of the storage section 2s. The horizontal shift registers transfer information charges output from the respective vertical shift registers of the storage section 2s to the output section 2d. The output section 2d is equipped with a reset transistor for discharging the capacity temporarily storing the charges transferred from the horizontal shift registers of the horizontal transfer section 2h.

The light focused onto the imaging section 2i is photo-electrically transformed to produce information charges with respective bits of the imaging section 2i. A two-dimensional matrix of the information charges produced by the imaging section 2i is transferred to the storage section 2s at a high speed by the vertical shift registers of the imaging section 2i. As a result, information charges for one frame are retained in the vertical shift registers of the storage section 2s. Next, the information charges are transferred for each line from the storage section 2s to the horizontal transfer section 2h. Then, the information charges are transferred from the horizontal transfer section 2h to the output section 2d pixel by pixel. The output section 2d converts the charges for each pixel into a voltage value to effect a change in the voltage value as a CCD output.

The imaging section 2i and the storage section 2s, as illustrated in FIGS. 5 to 7, are constituted by a plurality of shift registers formed in a surface region of a semiconductor substrate 10. FIG. 5 is a schematic plan view illustrating part of a conventional imaging part 2i and FIGS. 6 and 7 are sectional side views along lines A-A and B-B, respectively.

A P-well (PW) 11 to which P-type impurities have been added is formed in an N-type semiconductor substrate (N-SUB) 10. In a surface region of the P-well 11 is formed an N-well (NW) 12 to which have been added N-type impurities in high concentration. A separation region 20 is provided to separate channel regions of the vertical shift registers. Byion-injecting P-type impurities in parallel to each other at predetermined intervals, a P-type impurities region is formed in the N-well 12. The P-type impurities region corresponds to the separation region 20. The N-well 12 is electrically partitioned by the separation region 20 adjacent thereto, and a region sandwiched between the separation regions 20 becomes a channel region 22 through which information charges pass.

On a surface of the semiconductor substrate 10 is formed an insulating film 13. A plurality of transfer electrodes 24 constituted by polysilicon films are arranged in parallel to each other and perpendicular to the extension direction of the channel region 22 via the insulating film 13. A set of the three adjacent transfer electrodes 24-1, 24-2, 24-3 corresponds to one pixel.

FIG. 8 illustrates a timing chart of voltages applied to the transfer electrodes 24-1 to 24-3 at the time of image capture and transfer. FIG. 9 illustrates a state of potential distribution in the N-well 12 along the channel region 22 at the time of image capture. At the time of image capture, the electrode 24-2 of one set of transfer electrodes 24 is turned on to form a potential well 50 in the channel region 22 under the transfer electrode 24-2 and to turn off the remaining transfer electrodes 24-1, 24-3, thus storing information charges in the potential well 50 under the transfer electrode in an ON state. Then, a potential in the channel region 22 under the transfer electrodes 24-1, 24-2, 24-3 is controlled to transfer the information charges.

However, as a pixel of the CCD image sensor have more micronization, the capacity of the potential well 50 of each pixel becomes smaller, so that the amount of saturated charges capable of being stored in the potential well 50 becomes smaller, thus degrading imaging sensitivity. As illustrated in the timing chart of FIG. 10, the two transfer electrodes 24-1, 24-2 of one set of transfer electrodes 24 are turned on to form the potential well 50 in the channel region 22 under the two transfer electrodes 24-1, 24-2 and only the remaining transfer electrode 24-3 is turned off, thus increasing the capacity of the potential well 50 under the transfer electrodes in an ON state and improving sensitivity, which is called a two-gate-ON imaging method.

However, the two-gate-ON imaging method is problematic in that it is difficult to increase a saturated output because a potential barrier under the transfer electrodes 24-3 lowers at the time of image capture, resulting in a tendency for blooming, which causes information charges to leak between adjacent pixels, to occur.

### SUMMARY OF THE INVENTION

An imaging system according to the present invention includes at least three transfer electrodes and an imaging section in which pixels producing information charges as a result of receiving the light from the outside are continuously arranged for storage and transfer of the information charges by making use of potential wells formed by potentials applied to the transfer electrodes, thus maintaining one of the transfer electrodes in an ON state and alternately switching at least another one of the transfer electrodes between ON and OFF states during image capture.

### BRIEF DESCRIPTION OF THE DRAWINGS

Preferred embodiments of the present invention will be described in detail based on the following figures, wherein:

FIG. 1 is a schematic block diagram illustrating a configuration of a solid-state imaging system according to the present invention;

FIG. 2 is a timing chart at image capture and transfer by a solid-state imaging system according to the present invention;

FIGS. 3A and 3B are a view illustrating potential wells under transfer electrodes at image capture by a solid-state imaging system according to the present invention;

FIG. 4 is a view illustrating a configuration of a solid-state imaging device.

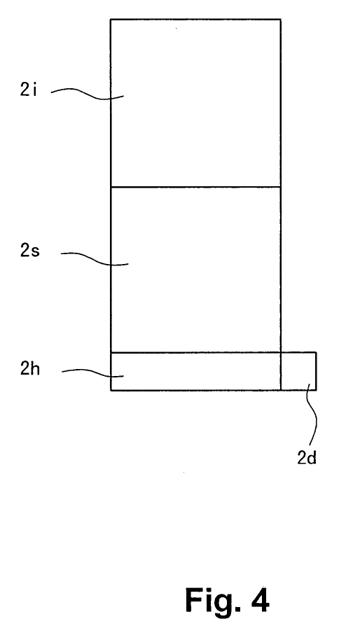

FIG. 5 is a plan view illustrating structures of an imaging section and a storage section of a solid-state imaging device;

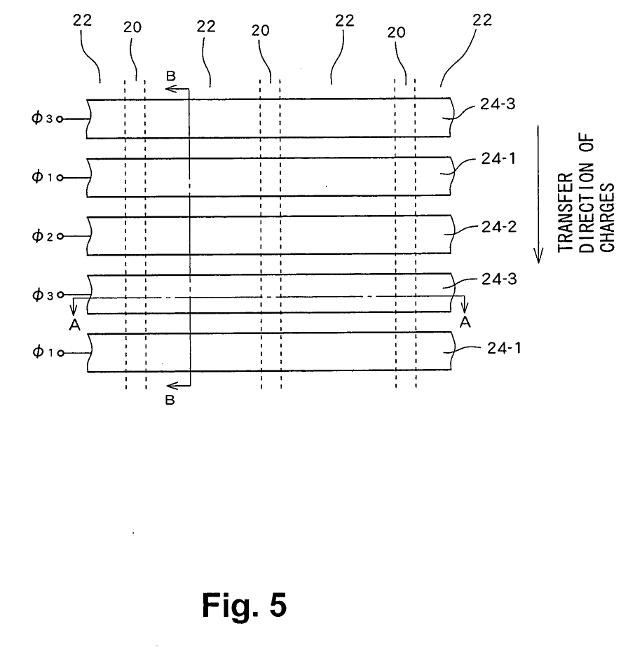

FIG. 6 is a sectional view illustrating structures of an imaging section and a storage section of a solid-state imaging device;

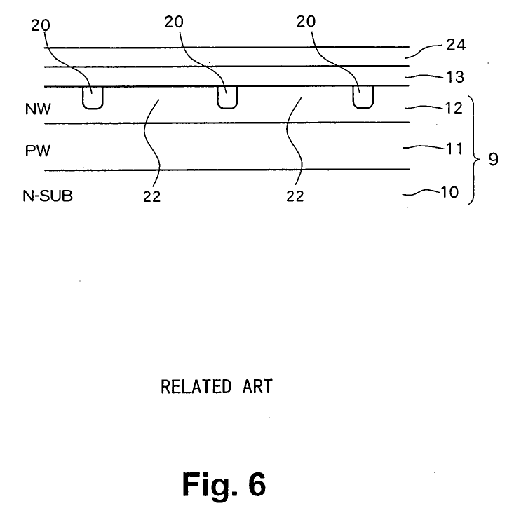

FIG. 7 is a sectional view illustrating structures of an imaging section and a storage section of a solid-state imaging device;

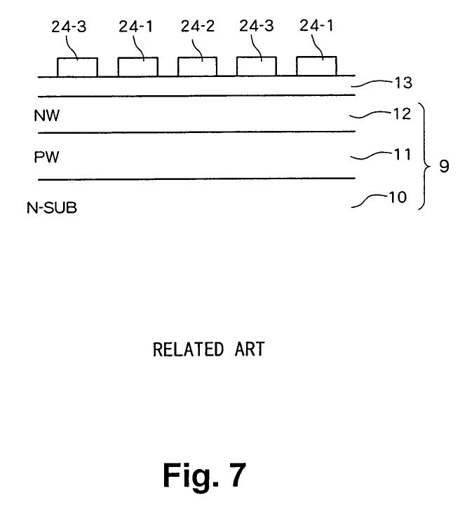

FIG. 8 is a timing chart at image capture and transfer by one-gate-on imaging method;

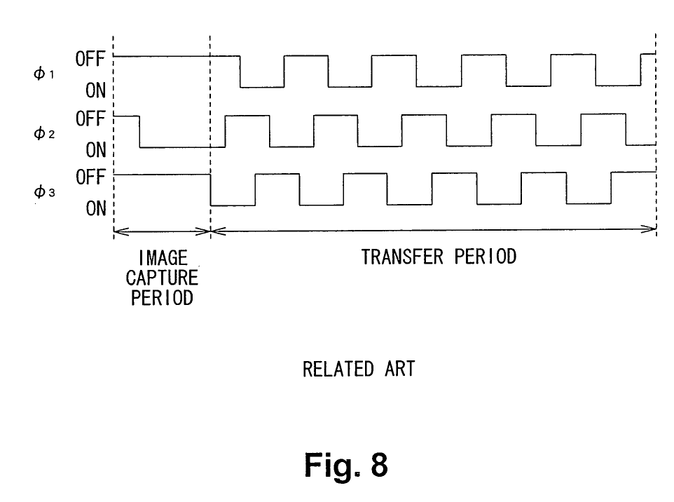

FIG. 9 is a view illustrating potential wells under transfer electrodes at image capture by a conventional solid-state imaging device; and

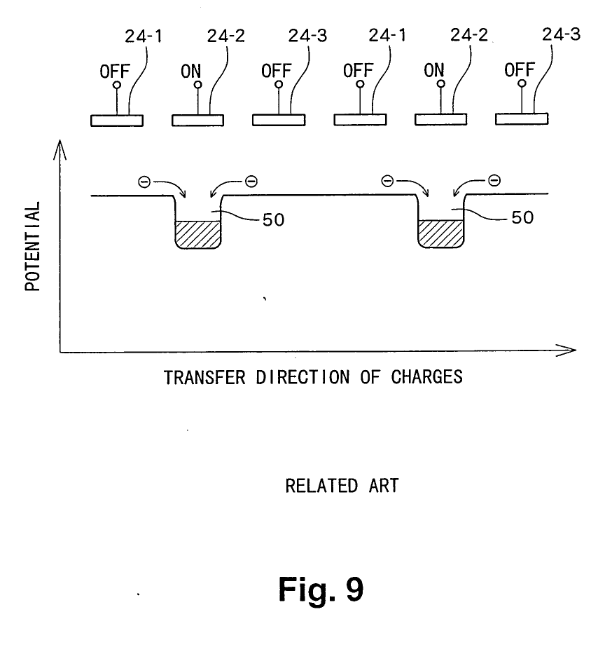

FIG. 10 is a timing chart at image capture and transfer by two-gate-on imaging method.

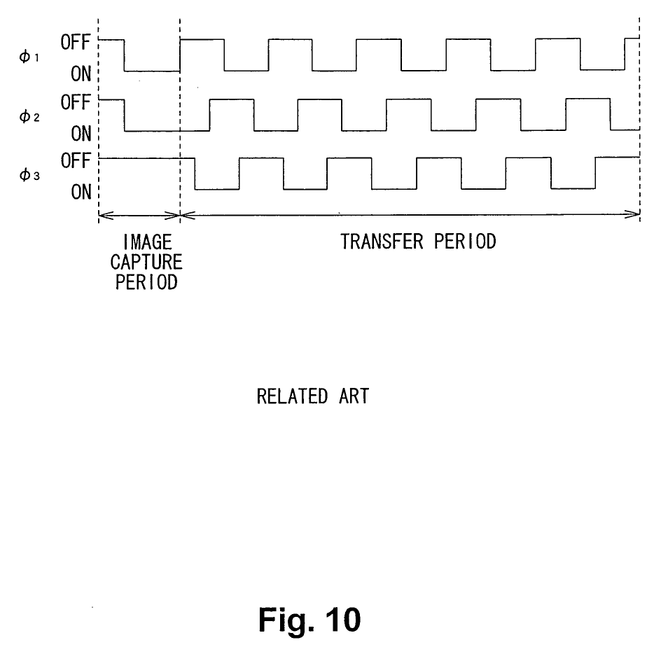

### DESCRIPTION OF THE PREFERRED EMBODIMENT

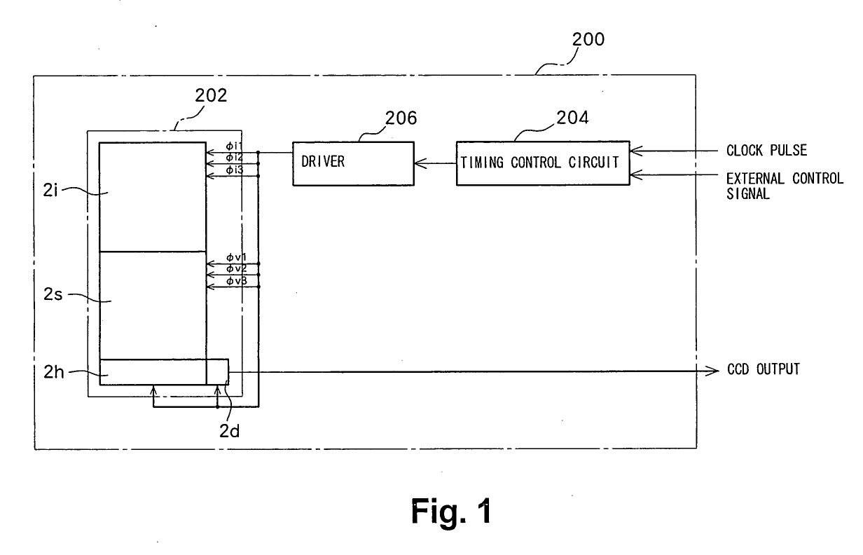

An imaging system 200 according to one preferred embodiment of the present invention includes a CCD solid image sensor 202, a timing control circuit 204, and a driver 206, as illustrated in FIG. 1.

The CCD image sensor 202 includes an imaging section 2i, a storage section 2s, a horizontal transfer section 2h and an output section 2d. The timing control circuit 204 produces control signals for controlling image capture, vertical transfer and horizontal transfer, and output of the CCD image sensor 202 in response to a clock pulse of a predetermined frequency and an external control signal. These control signals are input from the timing control circuit 204 to the driver 206. The driver 206 receives the control signals from the timing control circuit 204 and outputs a clock pulse to each of the imaging section 2i, the storage section 2s, the horizontal transfer section 2h, and the output section 2d at a required timing.

The imaging section 2i and the storage section 2s have vertical shift registers constituted by including a plurality of channel regions extended vertically (vertical direction in FIG. 1) in parallel to each other and a plurality of transfer electrodes crossing the channel regions. Each bit of the respective vertical shift registers functions as one of intercepting pixels continuously arranged in the transfer direction of information charges. The imaging section 2i and the storage section 2s may have a conventional structure. A set of three adjacent transfer electrodes 24-1, 24-2, 24-3 corresponds to one pixel. By applying a voltage to the transfer electrodes 24-1, 24-2, 24-3 of each pixel, information charges are stored (image capture) and transferred.

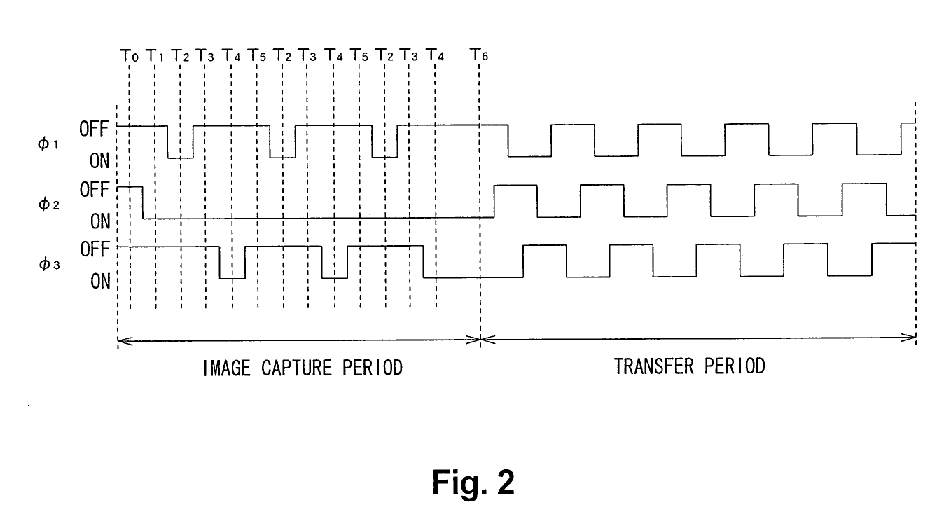

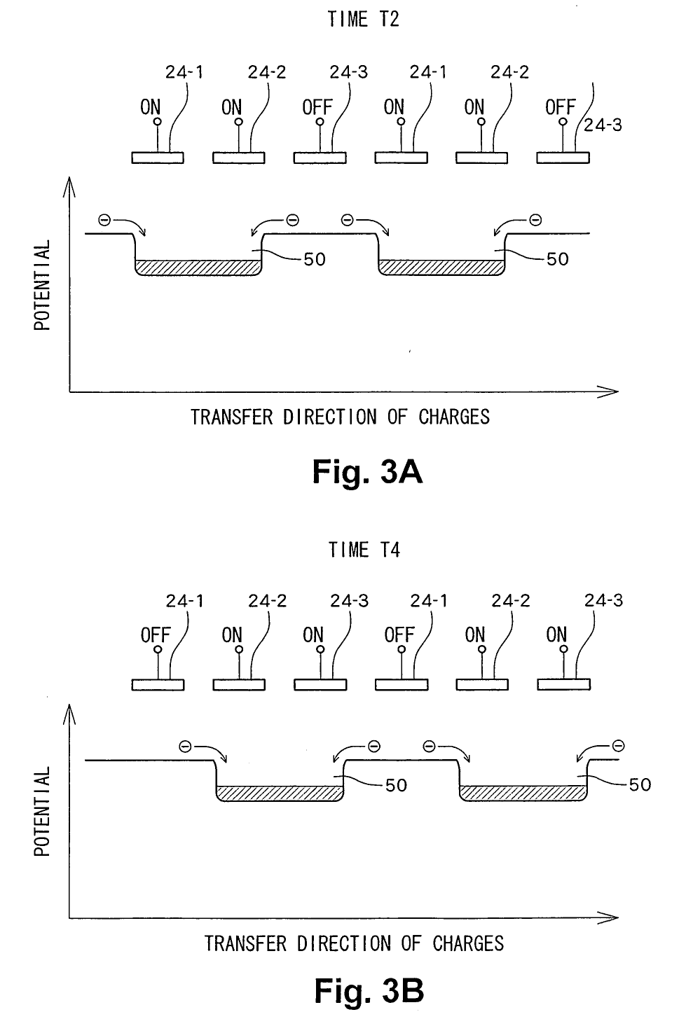

FIG. 2 illustrates a timing chart for image capture and transfer. In the timing chart, its ordinate indicates a potential and its abscissa indicates time. FIG. 3 illustrates a state of potential distribution in the N-well 12 along the channel region 22 at the time of image capture.

At image capture, one transfer electrode 24-2 of the set of transfer electrodes 24 is maintained in an ON state and the transfer electrodes 24-1 and 24-3 on both sides thereof are alternately switched to an ON state for image capture.

At time T₀, all the transfer electrodes 24-1 to 24-3 are set at a low level to operate an electronic shutter for discharging charges remaining in the imaging section 2i to a substrate deep section.

At time T₁, the transfer electrode 24-2 is set at a high level to obtain an ON state and the remaining transfer electrodes 24-1, 24-3 are maintained at a low level for an OFF state, thus forming a potential well in the channel region 22 under the transfer electrode 24-2. At time T₂, the transfer electrode 24-2 is maintained in an ON state and the state of the transfer electrode 24-1 is changed to a high level for a ON state. The transfer electrode 24-3 is kept at a low level to maintain the OFF state. At time T₃, the transfer electrode 24-2 is maintained in an ON state and the transfer electrode 24-1 is returned from the high level to a low level to obtain an OFF state. The transfer electrode 24-3 is kept at the low level to maintain the OFF state. At time T₄, the transfer electrode 24-2 is maintained in an ON state and the state of transfer electrode 24-3 is changed to a high level for an ON state. The transfer electrode 24-1 is kept at the low level to maintain the OFF state. At time T₅, the transfer electrode 24-2 is maintained in an ON state and the transfer electrode 24-3 is returned from the high level to a low level to obtain an OFF state. The transfer electrode 24-1 is kept at the low level to maintain the OFF state.

During an image capture, processing for the times T₂ to T₅ is repeated. For example, ON/OFF operations of the transfer electrodes 24-1, 24-3 are repeated at intervals of approximately 100 μs to 1 ms to increase the amount of saturated charges in the potential wells formed under the transfer electrodes 24-1 to 24-3 by approximately 30% as compared to the one-gate-on imaging method and to improve imaging sensitivity by approximately 10%. FIG. 3 illustrates that the amount of saturated charges in the potential wells is considered to increase at this time by formation of the potential wells in a spreading state into the channel region 22 under the transfer electrodes 24-1, 24-2 or the channel region 22 under the transfer electrodes 24-2, 24-3. Moreover, by setting switching intervals of ON/OFF operations of the transfer electrodes 24-1, 24-3 an interval shorter (e.g. approx. 100 μs) than the time during which the leakage of charges into adjacent pixels begins to increase, blooming can be restrained as compared to the two-gate-on imaging method.

A conventional imaging method of performing two-gate-on operation at image capture requires, to prevent the center of pixels from deviating during colored image capture, includes a step of displacing a position of a color filter from that in the case of the one-gate-on imaging method, so that the center of the color filter corresponds to the centers of the transfer electrodes 24-1 and 24-2. Accordingly, in the conventional art it is not possible to perform switching between the one-gate-on imaging method and two-gate-on imaging method without generation of any image deviation.

In this embodiment, an average position of the center of the potential wells formed at respective pixels during image capture is almost the center of the transfer electrode 24-2. Accordingly, it is sufficient to align the center of the transfer electrode 24-2 with that of a color filter in the same manner as when a one-gate-on imaging method is employed. As a result, it is possible to perform image between the conventional one-gate-on imaging method and the imaging method according to this embodiment without generation of any image deviation.

In this embodiment, image capture is performed by switching both of the transfer electrodes 24-1 and 24-3 disposed on both sides of the transfer electrode 24-2 in the center of these electrodes between an ON state and an OFF state. However, even if the image capture is performed by switching only one of either the transfer electrode 24-1 or the transfer electrode 24-3 between an ON state and an OFF state, the amount of saturated charges in the potential wells can be increased and imaging sensitivity can be also improved. However, because variations occur in the amount of generated dark current under the respective transfer electrodes, it is more preferable to average the amount of generated dark current under the transfer electrodes by switching the transfer electrodes between an ON state and an OFF state for image capture. This provides restraint of a difference in the amount of generated dark current between pixels, thus reducing image graininess.

During a transfer operation, as found at a stage from time T₆ onward in FIG. 2, three-phase transfer clocks φ1 to φ3 are applied for each combination of the three adjacent transfer electrodes 24-1, 24-2, 24-3. This controls the potentials of the channel region 22 under the transfer electrodes 24-1, 24-2, 24-3, so that information charges are transferred in an extending direction of the vertical shift registers.

Immediately before transfer of information charges begins, it is preferable to start a transfer operation from a condition in which two of the transfer electrodes 24-1 to 24-3 are in an ON state as found at a stage of time T₂ or time T₄. This provides shifting to transfer processing with the amount of saturated charges and sensitivity maintained during image capture.

The imaging system according to one embodiment of the present invention is capable of reducing blooming between pixels at the time of image capture and improving imaging sensitivity.

What is claimed is:

1. An imaging system, comprising an imaging section, which is continuously arranged with pixels having at least three transfer electrodes, for producing information charges in response to the light from the outside, wherein
the information charges are stored and transferred, using potential wells formed by electric potentials applied to the transfer electrodes, and
during image capture period, one of the transfer electrodes is maintained in an ON state and at least another one of the transfer electrodes is alternately switched between an ON state and an OFF state.

2. The imaging system according to claim 1, wherein, during image capture period, transfer electrodes on both sides of the transfer electrode maintained in the ON state are alternately switched to the ON state.

3. The imaging system according to claim 1, wherein, during image capture period, switching of the transfer electrodes between the ON state and the OFF state is performed in 100 μs to 1 ms.

4. The imaging system according to claim 2, wherein, during image capture period, switching of the transfer electrodes between the ON state and the OFF state is performed in 100 μs to 1 ms.

5. The imaging system according to claim 1, wherein one of the transfer electrodes alternately switched between the ON state and the OFF state is maintained in the ON state when image capture period is completed.

6. An imaging system driving method, comprising the following steps:
using the imaging system, which includes an imaging section continuously arranged with pixels having at least three transfer electrodes, for producing information charges in response to the light from the outside;
storing and transferring the information charges with potential wells formed by electric potentials applied to the transfer electrodes; and
during image capture period, maintaining one of the transfer electrodes in an ON state and alternately switching at least another one of the transfer electrodes between an ON state and an OFF state.

7. The imaging system driving method according to claim 6, wherein
during image capture period, transfer electrodes on both sides of the transfer electrode maintained in the ON state are alternately switched to the ON state.

8. The imaging system driving method according to claim 6, wherein
during image capture period, switching of the transfer electrodes between the ON state and the OFF state is performed in 100 μs to 1 ms.

9. The imaging system driving method according to claim 7, wherein
during image capture period, switching of the transfer electrodes between the ON state and the OFF state is performed in 100 μs to 1 ms.

10. The imaging system driving method according to claim 6, wherein
one of the transfer electrodes alternately switched between the ON state and the OFF state is maintained in the ON state when image capture period is completed.
